(19) United States
(12) Patent Application Publication
(10) Pub. No.: US 2025/0192551 A1
(43) Pub. Date: Jun. 12, 2025

(54) SYNCHRONIZATION OF FREQUENCY MEASUREMENTS IN A DEMAND RESPONSE SYSTEM

(71) Applicant: CENTRICA BUSINESS SOLUTIONS BELGIUM N.V., Antwerp (BE)

(72) Inventors: Evelyn HEYLEN, Antwerp (BE); Bert CLAESSENS, Antwerp (BE); Stef PEETERS, Antwerp (BE)

(21) Appl. No.: 18/838,830

(22) PCT Filed: Feb. 16, 2023
(86) PCT No.: PCT/EP2023/053954

§ 371 Date: Aug. 15, 2024

(30) Foreign Application Priority Data
Feb. 17, 2022 (GB) 2202112.5

(51) Int. Cl. H02J 3/08; H02J 3/00

(52) U.S. Cl. CPC H02J 3/08; H02J 3/001; H02J 2203/10

(57) ABSTRACT

Disclosed is a method of determining a synchronization offset for measurement data relating to an electrical power supply network. First and second data sets of measurement data are received from a first source and a second source. Each data set includes measurements of an electrical parameter of the network measured at the respective source together with time information indicating measurement times of the measurements. Correlation measures are determined for each of a plurality of time shift values, indicating correlation between a first set of measurement values derived from the first data set and a second set of measurement values derived from the second data set, with one of the first and second sets of measurement values being derived under application of a time shift corresponding to the respective time shift value. One of the time shift values is selected in dependence on the correlation measures and used to provide a synchronization offset. The synchronization offset is used to correct time information in measurement data from one of the sources.

The present invention relates to systems and methods for determining a synchronization offset for measurement data relating to an electrical power supply network and for synchronizing measurement data by correcting time information using the determined synchronization offset. Particular embodiments apply synchronization to frequency measurement data from demand response assets in a demand response system.

Grid operators find it increasingly challenging to manage aspects of their respective energy grids such as balancing electricity supply with demand and responding to frequency shifts in the electrical grid.

In general, a grid operator may mandate behaviour of (or provide financial incentives for) energy producers or energy consumers in order to ensure a stable and responsive electrical grid. For example, a grid operator may buy regulation capacity from industrial consumers and/or producers of power. A consumer or producer offering such a service will receive the mandate to reduce or increase their power consumption when required by the grid operator in order to maintain stability and quality of the grid. Such services are commonly referred to as flexibility services.

Flexibility services may be provided by large-scale industrial energy assets managed by commercial operators. However, it is becoming more widespread for smaller, private energy assets, such as energy storage and generation assets (e.g. solar panels, batteries, heatpumps and boilers) to be installed in residential or smaller-scale commercial settings, and attempts have been made to provide flexibility services by aggregating individual smaller assets into asset pools and managing the services at the pool level, for example by configuring complementary assets to implement aggregate demand response actions.

In principle, to use smaller energy assets, such as residential heat pumps, batteries, electric vehicles and boilers, to provide flexibility in power systems, e.g., frequency or voltage regulation, they should comply with strict requirements in terms of the accuracy of measurements of local system parameters, such as frequency and voltage. National Grid, for instance, requires that the reported time stamp of a measurement should maximally deviate 100 ms from the true time stamp. In practice, the measurements available for such assets often do not satisfy these requirements and it is too expensive to install very accurate local clocks on each asset. Whereas the relative difference between time stamps of cost-effective metering equipment is often fairly accurate, the absolute time stamps of measurements are not. However, a shift in absolute timing can significantly deteriorate the accuracy of the reported frequency value. Thus, while in principle it would be desirable to integrate small, low-value energy assets into flexibility systems, the limitations of those assets may prevent this.

The present invention seeks to alleviate some of these problems to allow assets with less accurate clocks to be integrated into a demand response system and to provide flexibility services.

Accordingly, in a first aspect of the invention, there is provided a method of determining a synchronization offset for measurement data relating to an electrical power supply network; the method comprising:
receiving a first data set of measurement data from a first source and a second data set of measurement data from a second source, each data set comprising:
   a plurality of measurements of an electrical parameter of the network measured at the respective source; and
   time information indicating measurement times of the measurements;
determining a plurality of correlation measures, wherein each correlation measure is determined for a respective one of a plurality of time shift values and is indicative of a correlation between:
   a first set of measurement values derived from the first data set; and
   a second set of measurement values derived from the second data set, wherein one of the first and second sets of measurement values is derived under application of a time shift corresponding to the respective time shift value;
selecting one of the time shift values in dependence on the correlation measures; and
determining a synchronization offset based on the selected time shift value.

Preferably the method may further comprise correcting timing information in measurement data received from one of the first and second sources using the determined synchronization offset. This may involve correcting the received data and/or receiving further measurement data from one of the first and second sources and correcting timing information in the further measurement data using the determined synchronization offset.

Alternatively (or additionally), the method may comprise outputting the synchronization offset, preferably by transmitting the synchronization offset to one of the first and second sources to enable local correction of measurement data at the source. The method may then comprise, at said source, receiving (and storing) the synchronization offset, correcting timing information in measurement data generated at said source using the synchronization offset, and transmitting the corrected data (e.g. to a central synchronization controller, demand response controller, or other system component as discussed later).

Correction preferably comprises applying the synchronization offset to timing information in measurement data from a source, e.g. by adding or subtracting the synchronization offset to/from timestamps in the measurement data that is to be corrected.

Preferably, one or both of the first and second sources comprise(s) a demand response asset configured to implement a flexibility service by altering supply of energy to and/or use of energy from the power supply network, for example in response to locally measured network conditions and/or under control of a central demand response system. Each source may also comprise or be associated with an asset controller for running a demand response control program to control energy flow to/from the network and/or a measurement device for measuring the electrical parameter of the network.

The electrical parameter is preferably one of: frequency; and voltage.

The method is preferably performed at a central synchronization controller in communication with the first and second sources via a data network.

Correlation is preferably determined between measurement values derived from the data sets for corresponding time instants after shifting data for the data sets relative to each other by the time shift value.

For example, the first set of measurement values may comprise measurements from the first data set, each associated in the first data set with a respective first measurement time value (e.g. as a measurement timestamp), and the second set of measurement values are derived from the second data set based on second measurement time values, the second measurement time values obtained by modifying (e.g. by addition/subtraction) each of the first measurement time values using the time shift value. The method may then further involve determining measurement values from the second data set that correspond to the second measurement time values (e.g. based on time information such as time stamps in the second data set). This step may use interpolation as discussed further below.

Preferably, the first set of measurement values is derived from the first data set over a predetermined time window (e.g. encompassing a certain time period and/or a certain number of measurement samples); the second set of measurement values is then preferably derived from the second data set over a corresponding time window shifted by the time shift value.

Deriving at least one of the first and second sets of measurement values may comprise interpolating from the measurements of the respective data set. Preferably, the first set of measurement values comprise measurements taken from the first data set, each associated in the first data set with a respective first measurement time value (e.g. measurement timestamp), and deriving the second set of measurement values preferably comprises performing interpolation on measurements of the second data set at time instants corresponding to the first measurement time values modified by the time shift value. More specifically, the second set of measurement values may be obtained by interpolating from the second data set at a plurality of time instants determined by applying the time shift value to time stamps of the measurement values from the first data set.

One of the first and second sources preferably corresponds to a source for which correction is to be performed, and the other source is a reference source. In examples described herein, correction may be performed for the first source, and the second source is the reference source. However, the roles of the first and second sources may be reversed. In an embodiment, the first source is an imprecise measurement source generating measurement data with timing information based on a first clock that is to be corrected, and the second source is a reference source generating measurement data with timing information based on a second clock, and the synchronization offset is used for correcting timing information in measurement data from the first source, where the timing information based on the first clock is preferably less accurate than the timing information based on the second clock.

Preferably, the selected time shift value is used as the synchronization offset (i.e. the synchronization offset is the same as the selected time shift value). However, alternatively post-processing may be applied to the selected time shift value to derive the synchronization offset (e.g. to implement filtering/smoothing of the offset over time when the offset is periodically recomputed).

The method preferably selects the time shift value associated with the correlation measure of the plurality of correlation measures that indicates the strongest correlation. Typically (though not necessarily) this may correspond to the highest correlation value. For example, the correlation measure may be a Pearson correlation measure. Correlation measures may be determined for a predetermined set of possible time shift values, e.g. configured as a fixed set of values, or the time shift values to be evaluated may e.g. be defined as a predetermined range of time shift values with a predetermined step size.

Preferably, the method comprises providing the synchronization offset to a given one of the sources and using the offset to correct a local time reference at the given source for controlling performance of one or more time-dependent actions at the given source.

Determination of the offset may be repeated one or more times (e.g. periodically) at fixed or variable intervals. In an example, the method may comprise determining a validity period for the synchronization offset, and repeating the offset determination upon expiry of the validity period, wherein the validity period is determined in dependence on one of: the current determined offset, changes in the determined offset over time; a rate of change or stability of the determined offset over time; and a type of energy asset of the first or second source. When correction is performed centrally, the controller may use the computed offset for correction until it is recomputed. Similarly, when performing correction locally at the source, the source may receive an offset and use it for correction until an updated offset is received from the controller.

The method may comprise performing the method of determining a synchronization offset for each of a plurality of sources to determine a respective synchronization offset for each source based on measurement data received from the respective source, and preferably using the respective synchronization offset to correct measurement data received from the respective source or transmitting the offset to the respective source for local time correction at the source. The synchronization offset for each of the sources for which correction is to be performed (e.g. corresponding to the first source) is preferably determined using measurement data from the same reference source (e.g. the second source). The method may comprise associating a respective validity period with each synchronization offset and recomputing the offsets after expiry of the respective validity periods, e.g. as set out above

The method may comprise selecting one of a plurality of available sources as the reference source (e.g. the second source) and using measurement data from the selected source in the method, the selection preferably made in dependence on proximity of the available sources to the source(s) for which correction is performed (e.g. the first source). The method may select as the reference source a source that is closest in the network (e.g. geographically or topologically) to the source for which correction is to be performed.

The method preferably comprises transmitting corrected measurement data having timing information corrected using the synchronization offset to a demand response control system and preferably further comprising performing demand response control based on the corrected measurement data at the control system.

In a further aspect, the invention provides a system comprising:
a synchronization controller;
a first source comprising a demand response asset connected to an electrical power supply network and configured to implement a flexibility service by altering supply of energy to and/or use of energy from the network, the first source configured to generate and transmit to the synchronization controller a first measurement data set;
a second source, preferably comprising a second demand response asset connected to the electrical power supply network, configured to generate and transmit to the synchronization controller a second measurement data set, wherein each of the first and second measurement data sets comprise:
   a plurality of measurements of an electrical parameter of the electrical power supply network measured at the respective source; and
   time information indicating measurement times of the measurements;
wherein the synchronization controller is configured to:
   receive the first and second data sets;
   determine a plurality of correlation measures, wherein each correlation measure is determined for a respective one of a plurality of time shift values and is indicative of a correlation between:
      a first set of measurement values derived from the first data set; and
      a second set of measurement values derived from the second data set, wherein one of the first and second sets of measurement values are derived under application of a time shift corresponding to the respective time shift value;
   select one of the time shift values in dependence on the correlation measures;
   determine a synchronization offset based on the selected time shift value; and
   use the determined synchronization offset to perform at least one of:
      correcting time information in measurement data received from the first (or second) source and outputting the corrected measurement data; and
      transmitting the synchronization offset to the first (or second) source to enable local correction of time information at the first (or second source.

The invention also provides computer program, computer program product or tangible computer readable medium comprising software code adapted, when executed on a data processing apparatus, to perform any method as set out herein.

The invention also provides a system or a synchronization controller having means, optionally in the form of one or more processing devices with associated memory, for performing any method as set herein.

Any feature in one aspect of the invention may be applied to other aspects of the invention, in any appropriate combination. In particular, method aspects may be applied to apparatus and computer program aspects, and vice versa.

Furthermore, features implemented in hardware may generally be implemented in software, and vice versa. Any reference to software and hardware features herein should be construed accordingly.

Preferred features of the present invention will now be described, purely by way of example, with reference to the accompanying drawings, in which:—

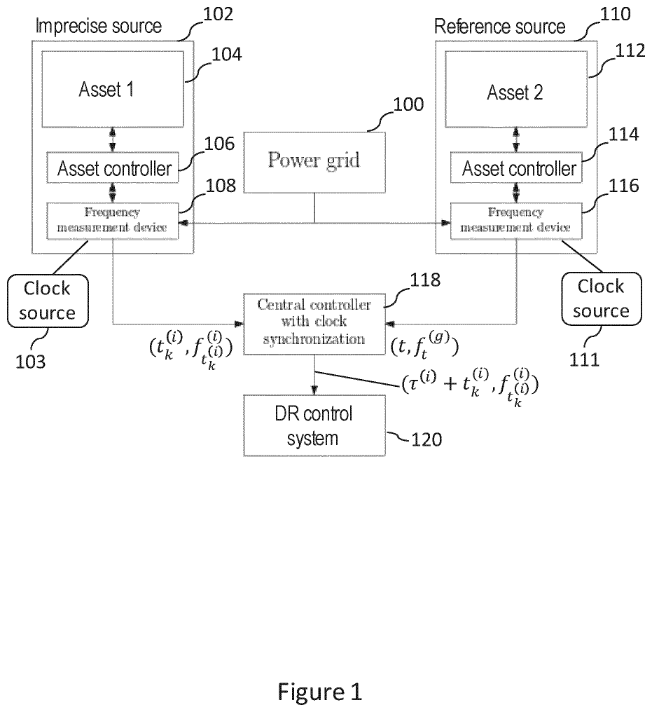

FIG. 1 illustrates a synchronization system for a demand response system in overview;

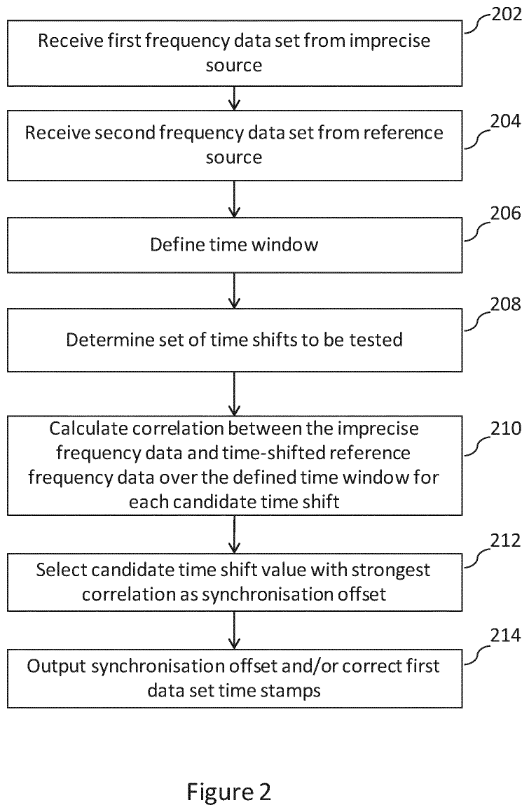

FIG. 2 illustrates a synchronization method;

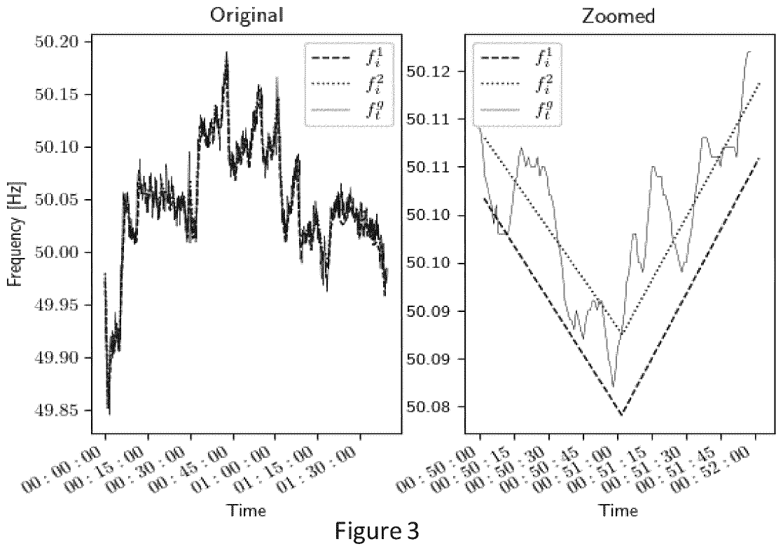

FIG. 3 illustrates frequency measurement data sets from imprecise assets and from a reference source; and

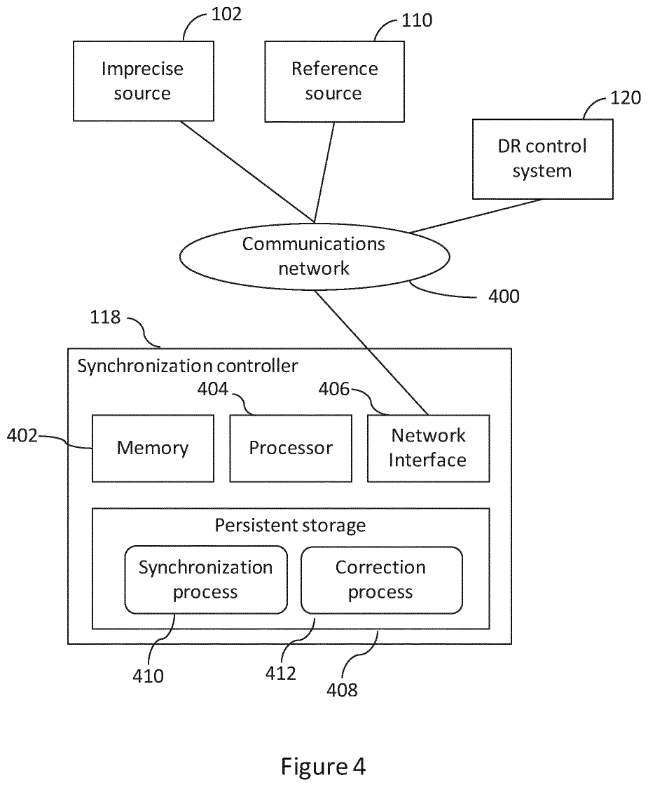

FIG. 4 illustrates a computing device for implementing described techniques.

### OVERVIEW

The present disclosure relates to demand response systems employing energy assets to provide flexibility services in an electricity distribution grid. The term “asset” or “energy asset” preferably refers to any device, machine or other facility (or collection of such entities) arranged to provide energy to or use energy from the power distribution grid. A flexibility asset or demand response asset is an asset that is configured to, or capable of, participating in a demand response system, by altering energy flow between the asset and the grid on demand, e.g. based on local grid conditions (such as grid frequency) and/or central command. Energy flow encompasses both flow to the grid from an asset (energy supply into the grid) and flow from the grid to an asset (energy use from the grid).

An asset may be an energy providing asset, an energy using asset, or both. An energy using asset may be considered a receiver (or consumer) of energy from the grid and may e.g. be an industrial load such as a factory or machine, an electrical vehicle charging point, a domestic electricity supply point or domestic load, an energy storage device partially or fully discharged that requires recharging, or the like. An energy providing asset may, for example, be a generator (e.g. a petrol generator, wind turbine, solar panel etc.) or an energy storage device such as a battery. Multiple individual energy using and/or supplying devices may operate together as a single asset (e.g. turbines in a windfarm, various machines and systems in a factory). In some cases, an asset may be able to both supply energy to, and receive energy from the grid (e.g. a factory with onsite generator using excess energy from the grid and supplying excess generating capacity to the grid at different times, or a battery able to store power drawn from the grid and supply the stored power back to the grid at a later time).

An asset may provide a demand response service by increasing or reducing energy usage (for an energy using asset) or by increasing or reducing supply (for an energy providing asset). For example, assets may alter their usage/supply to counteract frequency instabilities on the grid and keep the grid frequency within standard tolerances of the nominal frequency (e.g. 50 Hz in Europe or 60 Hz in the US). Assets may measure local grid conditions such as frequency and/or voltage and use those measurements to control the local demand response and/or may report such measurements to a central demand response control system, to other assets etc.

Embodiments of the invention provide a process for correcting measurement data from energy assets that have limited clock accuracy. This may typically apply to smaller, low-value assets that may be installed e.g. in residential or commercial settings. One class of such assets are network-connected to allow communication with a central DR (demand response) control system, for the purpose of reporting frequency measurements and implementing DR control actions. Such assets are also referred to herein as IoT (Internet of Things) assets. However, while the discussion here focusses on this class of asset, it should be understood that the present techniques can be used with any assets or other measurement sources where some correction of timing information in reported measurement data may be desirable.

To improve the measurement accuracy of IoT assets and facilitate their integration in pools for flexibility provision, embodiments of the invention provide a synchronization process that allows the accuracy of the reported absolute time stamp of IoT assets to be improved by using the frequency values of neighbouring assets with (more) accurate frequency measurements, both in terms of absolute time reporting and frequency value.

A demand response system implementing the synchronization process for frequency regulation applications is illustrated in overview in FIG. 1, which shows two measurement sources, an imprecise source 102 and a reference source 110. Typically, the different sources represent respective flexibility assets connected to a power grid 100 to participate in the provision of flexibility/demand response services.

Imprecise source 102 includes a first energy asset 104, an asset controller 106 and a frequency measurement device 108. Similarly, reference source 110 includes a second energy asset 112, an asset controller 114 and a frequency measurement device 116. The assets 104 and 112 are the energy assets that actually provide the flexibility service, e.g. variable power usage from the power grid (for loads and storage devices e.g. batteries) or variable power supply to the power grid (for power generators and storage devices e.g. batteries). Note that the components such as assets, asset controllers and frequency measurement devices may be separate components or may be integrated into fewer devices. For example, the frequency measurement device and/or asset controller may be embedded in the energy asset or alternatively the frequency measurement device could be integrated into a separate asset controller.

Asset controllers 106/114 are control devices implementing the control logic that performs some demand response action based on locally measured frequency. Frequency measurement devices 108 and 116 measure the frequency on the power grid at each asset. Frequency measurement device 108 at imprecise source 102 generates its measurement data based on an imprecise clock source 103 (e.g. a cheap local oscillator), while reference source 110 uses a more precise clock source 111, for example an accurate local clock synchronized to a remote atomic clock.

In more detail, frequency measurement device 108 provides frequency measurement data to a central controller 118, in the form of a time series of data tuples

$$( {t}_{k}^{( i )} , {f}_{{t}_{k}^{( i )}}^{( i )} ) ,$$

where i identifies the imprecise source (since the system may support synchronization of any number of imprecise sources using a single reference source); tₖ⁽ⁱ⁾ represents timestamps based on the local imprecise clock source 103 and

$${f}_{{t}_{k}^{( i )}}^{( i )}$$

represents the frequency measurements from the imprecise source with reported time instants tₖ⁽ⁱ⁾.

Frequency measurement device 116 also provides frequency measurement data to central controller 118, in the form of a time series of data tuples (t, ƒₜ^{(g)}), where g denotes the reference source, t represents timestamps based on the precise clock source 111 and ƒₜ^{(g)} represents the frequency measurements from the reference source with accurate time stamps t.

Thus, due to the difference in precision between the clock sources, the time stamps tₖ⁽ⁱ⁾ accompanying frequency measurements generated by imprecise source 102 will generally be less accurate than those generated by reference source 110.

The central controller 118 implements a synchronization algorithm to correct the timing information in the frequency data received from the imprecise source and provides the corrected data stream to a DR control system 120 to be processed further. The corrected data stream is shown as

$$( {τ}^{( i )} + {t}_{k}^{( i )} , {f}_{{t}_{k}^{( i )}}^{( i )} )$$

in FIG. 1, where the imprecise time stamps tₖ⁽ⁱ⁾ have been adjusted by adding a synchronization offset τ^{(t)} (determined for the specific imprecise asset i). Instead of centrally correcting the data, the central controller 118 may provide the synchronization offset back to the imprecise source 102 for local correction as described in more detail later.

### Synchronization Process

The synchronization algorithm relies upon an optimization formulation that identifies the absolute time stamp for each imprecise source with a reasonable accuracy based on underlying statistical correlation analysis. The algorithm relies upon the assumption that the frequency measured at a reference source is strongly correlated with the frequency to be measured at the imprecise source(s) (and thus the shape of the frequency signals will correspond). This is generally reasonable to assume given the physics behind power systems.

To identify the correct absolute time stamp (where the “correct” time is the time as given by the reference source clock), the optimization identifies the lag between the frequency measurements of the imprecise source and the frequency measurements with accurate absolute time stamps received from the reference source.

The process, as performed e.g. at the synchronization controller 118 of FIG. 1, is illustrated in FIG. 2.

In step 202, a first frequency data set is received at the controller from an imprecise source, such as source 102 of FIG. 1. In step 204, a second frequency data set is received at the controller from a reference source, such as source 110 of FIG. 1. The data sets include time series of frequency measurements with associated measurement time stamps as described above. Data sets may be received as bulk downloads but more typically the controller receives continuous streams of frequency data from the sources over a data network.

In step 206 a correlation time window is determined. For example, this could be a window of fixed duration starting at or centred at some reference time (e.g. the time at which the synchronization process is being run). Alternatively, the window could be defined as including a fixed number of sequential samples of the measurement data from the imprecise source. In an example, a window size of between 400 and 10000 samples may be used (e.g. this range may be appropriate for 1 minute resolution data; for higher resolution data e.g. 1 second resolution data even smaller window sizes may be usable). Thus, the window size may typically depend on the sample resolutions of the data sets and shorter or longer window sizes than the above range may be used depending on the data. In step 208, a set of candidate time shifts to be evaluated is obtained. This may be a fixed, preconfigured set of time shift values configured by an operator and could e.g. be defined as an array of time shift values or as a range (e.g. minimum and maximum) and step size (determining a resolution). For example, time shifts of between −1 second and +1 second at a 10 ms step size may be evaluated.

In step 210, a correlation value is then calculated for each candidate time shift value over the defined time window, indicating the correlation between a time-shifted version of the second data set (from the reference source), shifted by the candidate time shift value, and the first data set (that is to be corrected) over that window. In practice, this step may typically be implemented as a loop, stepping through a sequence of time shift values and computing correlations at each time shift. However, correlations for different time shift values could also be computed in parallel (e.g. by parallel processes processing subranges of the time shift values).

The correlation is computed based on mapping frequency measurement values from the imprecise source (over the defined window) at time instants tₖ⁽ⁱ⁾ to corresponding frequency measurement values from the reference source at time instants tₖ⁽ⁱ⁾+τ (in accordance with the respective time stamps provided in each data set) for the time shift τ being evaluated (on the basis that if there was no lag between the clocks, then time stamps tₖ⁽ⁱ⁾ based on imprecise clock 103 would equal the time stamps t from the reference source based on precise clock 111). As described in more detail below, the correlation interpolates from the frequency samples of the reference source to allow for the fact that the frequency samples in the different data sets may not be time-aligned and may be at different temporal resolutions (and thus there may not be a frequency measurement in the reference source data set with a time stamp matching a given time value tₖ⁽ⁱ⁾+τ that is derived from a time stamp of the imprecise source data set). The correlation is thus computed between the frequency samples of the imprecise source over the time window, and a corresponding set of time-shifted, interpolated frequency values derived from the reference source samples.

In step 212, the process then selects the time shift value that produced the strongest correlation (e.g. the maximum correlation value, depending on the correlation measure used) as the optimal time shift value, and this value is then adopted as a synchronization offset.

Correction of the time stamps of the imprecise data set is then performed using the determined synchronization offset in step 214. This involves computing for each frequency sample

$$( {t}_{k}^{( i )} , {f}_{{t}_{k}^{( i )}}^{( i )} )$$

from the imprecise source a time-corrected sample

$$( {τ}^{( i )} + {t}_{k}^{( i )} , {f}_{{t}_{k}^{( i )}}^{( i )} )$$

using the determined synchronization offset τ^{(t)}. The correction may be performed on the already received data from the imprecise source or may be applied to new data received subsequently (or both). Alternatively, the synchronization offset may be provided to the imprecise source (or to another system) to enable correction to be applied at the source (or other system).

The search for the optimal synchronization offset is summarised by the following equation:

$${τ}^{( i )} = {arg max}_{τ} ρ ( {f}_{{t}_{k}^{( i )}}^{( i )} , {f}^{( g )} ( {t}_{k}^{( i )} + τ ) ) \qquad ( 1 )$$

As mentioned above, ƒₜ^{(g)} represents the reference frequency measurements, which are considered accurate (with accurate time stamps) and are typically provided at a fixed resolution, for example a resolution of 1 second

$${f}_{{t}_{k}^{( i )}}^{( i )}$$

represents the imprecise frequency measurements (with imprecise time stamps) from the imprecise source with reported time instants tₖ⁽ⁱ⁾.

The imprecise frequency measurements may often have a variable resolution and/or lower resolution than the reference frequency measurements. By way of example, FIG. 3 shows time series of frequency measurements for two assets (ƒᵢ¹ and ƒᵢ²), as well as a series of reference frequency measurements (ƒₜ^{(g)} with 1-second resolution. The graph on the right shows a zoomed in view of the signal on the left extending from time 00:50:00 to 00:52:00.

In equation (1), ƒ^{(g)}(.) represents a 1D interpolation of ƒₜ^{(g)}, which is evaluated at tₖ⁽ⁱ⁾+τ with a time shift τ under analysis. The interpolation is computed dynamically during evaluation of the correlation. In some implementations, a linear interpolation may be used (such as the default scipy interp1D function) but other forms of interpolation could be used, such as quadratic or spline interpolation. ρ(.) is a function calculating the correlation coefficient between the frequency time series measured at the imprecise source and shifted versions of the reference source's frequency measurements. The latter relies upon the accurate knowledge of the relative differences between the timestamps of the imprecise frequency measurements Δtₖ⁽ⁱ⁾. This is generally the case since for imprecise sources with less accurate clocks, the time duration between imprecise time stamps is generally reliable, even though the absolute time values may be inaccurate (e.g. running ahead or behind by some time shift).

Any suitable correlation measure can be used for ρ. In an embodiment, a Pearson correlation measure is used, more specifically the Pearson product-moment correlation coefficient. This may be computed as follows:

$$ρ ( X , Y ) = \frac{E [ X - E ( X ) ) ( Y - E ( Y ) ) ]}{\sqrt{Var ( X ) Var ( Y )}} \qquad ( 2 )$$

Here X and Y are vectors of the frequency values over the window over which correlation is being computed. E(.) is a function computing the expected value of a vector of values and Var(.) is a function computing the variance of a vector of values.

Correlation is evaluated by searching over a maximum window size of potential time shift values. In typical examples, the window size is of the order of seconds to minutes. Values of the time offset t are evaluated at fixed time increments across the maximum window size. In typical examples, the time resolution is of the order of 1-10 ms. The window size and time resolution within that window define the values of t that are evaluated iteratively. For example, the process may iterate with t ranging from −60 to +60 seconds in 10 ms increments.

The process is summarized in the following pseudo-code:
1. Create the 1D interpolation function ƒ^{(g)}(.) of the reference frequency measurements with accurate clock.
2. Define an array t of potential shifts to be tested.
3. Loop over the array t of potential shifts with iterator q
   a. Shift the time instants of the inaccurate clock with the tested time shift τ_{q} from t to produce set of shifted timestamps t_{shift}_{_{q}}
   b. Use the interpolation function ƒ^{(g)}(.) to downsample the reference frequency measurements with accurate clock by evaluating them at the time instants t_{shift}_{_{q}}.
   c. Calculate the correlation ρ_{q} according to Eq. (2) between the downsampled and shifted reference frequency measurements and the frequency measurements with inaccurate clock from the imprecise source.
   d. Store the calculated ρ_{q} in an array ρ
4. Find the index q* of the largest ρ_{q} in ρ.
5. Find the appropriate time shift τ_{q*} at index q* in T.
6. Output τ_{q*} and/or use τ_{q*} to correct frequency data from the imprecise source

Note that while in the above example, the process is described as evaluating correlation by time-shifting the reference source, the process could alternatively time-shift the imprecise measurements (and similarly interpolation could be applied to the imprecise measurements instead of the reference measurements). The described approach is preferred because the reference source measurements are assumed to be provided at a fixed time resolution and at higher resolution that the imprecise measurements, but the approach can be varied depending on the nature of the data sources.

While FIG. 1 shows a single imprecise source, controller 118 may receive frequency measurements from multiple different imprecise sources and apply the above process to generate a respective synchronization offset for each source, which is used to correct the data stream from that source (and/or which is transmitted to that source). Frequency data from multiple sources may be corrected in this way using a single reference source 110.

In some cases, multiple reference sources with accurate clocks may be available in the grid. In that case, the central controller may select a particular reference source for correction of data from a given imprecise source. Typically, a closest reference source (e.g. in terms of network topological distance or geographical distance) may be chosen on the assumption that assets that are located close to each other on the network will exhibit highest correlation between frequency measurements. However, for frequency measurements where it can be assumed that the frequency is largely similar across the network, any suitable reference source (with a sufficiently accurate clock) may be chosen.

In the FIG. 1 approach, the central controller computes the synchronization offset for the imprecise source 102 and then uses the offset to correct the timestamps of the frequency measurement data received from the imprecise source, providing the corrected data to the DR control system 120 or some other system where the measurement data is to be used. In preferred embodiments, the controller may periodically recompute the offset, for example at fixed or variable intervals, and then apply the updated offset to subsequently received data.

However, in an alternative arrangement, the controller may transmit the computed offset to the imprecise source, and the source performs the correction itself on subsequently obtained measurement data, resulting in a time-corrected data stream being sent from the source to the controller. In that case, the central controller may still periodically repeat the synchronization algorithm (taking into account that the received measurements already include some correction), and if necessary generate and send an updated correction to the imprecise source. The imprecise source uses the received offset to apply corrections until such time as an updated offset is received from the controller.

In either case (central correction at the controller, or providing an offset to the source for local correction), the controller can run the synchronization algorithm at a fixed update interval, or alternatively can determine when to update the synchronization offset dynamically, for example based on the type of the asset, the received measurement data, the computed offset and/or the conditions in the grid. In one example, the controller may determine how much/how fast the synchronization offset is changing (e.g. by tracking a rate of change of the synchronization offset, or monitoring the absolute difference between successive values of the offset) and use that to determine the next update interval. For example, if the rate of change of the offset, or the change in offset between the most recent offset and the current calculated offset, exceeds some threshold, then the controller may set the next update interval to be shorter as the offset may be considered unstable and thus require more frequent recalculation. On the other hand, if the offset is relatively stable (e.g. little change over successive computations/low rate of change) then a longer update interval may be set to avoid unnecessary computations and communication traffic with the imprecise source.

Thus, when computing an offset for each imprecise source, the process may also determine a validity time for the offset based on current conditions (e.g. using the criteria such as stability of the offset as described above and/or other criteria such as asset type). On expiry of the validity time for an offset computed for a given asset, the controller repeats the synchronization process to compute a new offset for the asset. As a result, the validity times and hence synchronization frequency for different assets may be different.

This approach allows the system to cope efficiently with situations where the offset changes over time (e.g. progressive clock drift), as long as the offset is stable for long enough to provide sufficient data to perform the synchronization algorithm.

While in the FIG. 1 example, the reference source is another demand response asset, any source of frequency measurements with accurate clock can be used as the reference source. For example, a standalone frequency measurement device measuring the frequency on the grid could be used.

The corrected data may be used by the DR control system 120 of FIG. 1, for example to determine whether the DR asset is delivering the required control response or how well the response has been implemented (e.g. as part of settlement with DR service providers), or to make adjustments to DR control. If the control system determines that the response from an asset is inadequate it may send modified control instructions to the asset, disable DR provision from the asset, and/or identify and configure alternative/additional assets to provide the required DR service.

More generally, the corrected data can be used for any other processes where time-accurate measurement data is needed, including to implement time-dependent actions (such as changing charging rates for smart energy tariffs), whether at the central controller 118/DR control system 120 or at the imprecise source 102. The offset may also be provided to the imprecise source 102 to allow local clock correction for any time-dependent actions, not just for correction of the frequency data. For example, the asset controller 106 at the source can use the time offset as a general clock correction to correct time information used in control processes, network communications with other systems etc.

While described above in relation to frequency measurements, the same approach may be used to correct timing information for other measurements of operating characteristics of the electricity grid, in particular voltage measurements. Voltage may generally be less consistent across the distribution network than frequency so for voltage measurements it may be preferable to use reference sources that are located relatively close in the network to the imprecise sources for which correction is required.

Furthermore, while the synchronization process has been described in relation to measurements on electricity grids, especially for demand response assets, the described principles may be applied to any other context where measurement data measuring physical characteristics of some physical system is obtained from two sources, where measurements from the sources are expected to be closely correlated but one of the sources has a less accurate clock than the other.

### System Architecture

FIG. 4 illustrates an example computing device for implementing the synchronization controller 118. The controller includes one or more processors 404 together with volatile/random access memory 402 for storing temporary data and software code being executed.

A network interface 406 is provided for communication with other system components (e.g. imprecise source 102, reference source 110 and DR control system 120) over one or more networks 400 (e.g. Local or Wide Area Networks, including the Internet).

Persistent storage 408 (e.g. in the form of hard disk storage, optical storage and the like) persistently stores control software for performing the controller functions, including a synchronization process 410 for carrying out the described synchronization and determining synchronization offsets, and a correction process 412 for correcting received frequency data streams using the determined synchronization offsets. The persistent storage also includes other software and data (not shown), such as an operating system for the controller.

The controller may be implemented using conventional computer server hardware and will include other conventional hardware and software components as known to those skilled in the art.

While a specific architecture is shown by way of example, any appropriate hardware/software architecture may be employed to implement the controller.

Furthermore, functional components indicated as separate may be combined and vice versa. For example, the synchronization process 410 and correction process 412 may run on the same controller (e.g. in parallel), or these processes may run on separate processing devices. In either case, processing may be split across multiple controllers, for example to provide separate controllers supporting different subpopulations of sources/DR assets for which correction is being performed. The functions of the controller could also be integrated into the DR control system 120 or into one of the sources 102/110.

It will be understood that the present invention has been described above purely by way of example, and modification of detail can be made within the scope of the invention.

1. A method of determining a synchronization offset for measurement data relating to an electrical power supply network; the method comprising:
receiving a first data set of measurement data from a first source and a second data set of measurement data from a second source, each data set comprising:
a plurality of measurements of an electrical parameter of the network measured at the respective source; and
time information indicating measurement times of the measurements;
determining a plurality of correlation measures, wherein each correlation measure is determined for a respective one of a plurality of time shift values and is indicative of a correlation between:
a first set of measurement values derived from the first data set; and
a second set of measurement values derived from the second data set, wherein one of the first and second set of measurement values is derived under application of a time shift corresponding to the respective time shift value;
selecting one of the time shift values in dependence on the correlation measures; and
determining a synchronization offset based on the selected time shift value.

2. A method according to claim 1, comprising correcting timing information in measurement data received from one of the first and second sources using the determined synchronization offset.

3. A method according to claim 1, comprising transmitting the synchronization offset to one of the first and second sources to enable local correction of measurement data at the source.

4. A method according to claim 1,
wherein one or both of the first and second sources comprise(s) a demand response asset configured to implement a flexibility service by altering supply of energy to and/or use of energy from the power supply network.

5. A method according to claim 1, wherein the electrical parameter is one of:
frequency; and
voltage.

6. A method according to claim 1,
performed at a central synchronization controller in communication with the first and second sources via a data network.

7. A method according to claim 1, wherein the first set of measurement values comprises measurements from the first data set, each associated in the first data set with a respective first measurement time value, and wherein the second set of measurement values are derived from the second data set based on second measurement time values, the second measurement time values obtained by modifying each of the first measurement time values using the time shift value.

8. A method according to claim 1, wherein the first set of measurement values is derived from the first data set over a predetermined time window and preferably wherein the second set of measurement values is derived from the second data set over a corresponding time window shifted by the time shift value.

9. A method according to claim 1, wherein deriving at least one of the first and second sets of measurement values comprises interpolating from the measurements of the respective data set.

10. A method according to claim 9, wherein the first set of measurement values comprise measurements taken from the first data set, each associated in the first data set with a respective first measurement time value, and wherein deriving the second set of measurement values comprises performing interpolation on measurements of the second data set at time instants corresponding to the first measurement time values modified by the time shift value.

11. A method according to claim 1, wherein the first source is an imprecise measurement source generating measurement data with timing information based on a first clock that is to be corrected, and the second source is a reference source generating measurement data with timing information based on a second clock, and wherein the synchronization offset is used for correcting timing information in measurement data from the first source.

12. A method according to claim 11, wherein the timing information based on the first clock is less accurate than the timing information based on the second clock.

13. A method according to claim 1, comprising using the selected time shift value as the synchronization offset.

14. A method according to claim 1, comprising selecting the time shift value associated with the correlation measure of the plurality of correlation measures that indicates the strongest correlation.

15. A method according to claim 1, comprising providing the synchronization offset to a given one of the sources and using the offset to correct a local time reference at the given source for controlling performance of one or more time-dependent actions at the given source.

16. A method according to claim 1, comprising repeating the determination of the offset at fixed or variable intervals.

17. A method according to claim 1, comprising determining a validity period for the synchronization offset, and repeating the offset determination upon expiry of the validity period, wherein the validity period is determined in dependence on one of:
the current determined offset,
changes in the determined offset over time;
a rate of change or stability of the determined offset over time; and
a type of energy asset of the first or second source.

18. A method according to claim 1, comprising performing the method of determining a synchronization offset for each of a plurality of sources to determine a respective synchronization offset for each source based on measurement data received from the respective source, and preferably using the respective synchronization offset to correct measurement data received from the respective source or transmitting the offset to the respective source for local time correction at the source.

19. A method according to claim 18, wherein the synchronization offset for each of the sources is determined using measurement data from the same reference source.

20. A method according to claim 18, comprising associating a respective validity period with each synchronization offset and recomputing the offsets after expiry of the respective validity periods.

21. A method according to claim 1, comprising selecting one of a plurality of available sources as a reference source (e.g. the second source) and using measurement data from the selected source in the method, the selection preferably made in dependence on proximity of the available sources to the source(s) for which correction is to be performed (e.g. the first source).

22. A method according to claim 1, comprising transmitting corrected measurement data having timing information corrected using the synchronization offset to a demand response control system and preferably further comprising performing demand response control based on the corrected measurement data at the control system.

23. A computer program, computer program product or tangible computer readable medium comprising software code adapted, when executed on a data processing apparatus, to perform a method as set out in claim 1.

24. A system having means, optionally in the form of one or more processing devices with associated memory, for performing a method as set out in claim 1.

25. A system comprising:
a synchronization controller;
a first source comprising a demand response asset connected to an electrical power supply network and configured to implement a flexibility service by altering supply of energy to and/or use of energy from the network, the first source configured to generate and transmit to the synchronization controller a first measurement data set;
a second source, preferably comprising a second demand response asset connected to the electrical power supply network, configured to generate and transmit to the synchronization controller a second measurement data set, wherein each of the first and second measurement data sets comprise:
a plurality of measurements of an electrical parameter of the electrical power supply network measured at the respective source; and
time information indicating measurement times of the measurements; wherein the synchronization controller is configured to:
receive the first and second data sets;
determine a plurality of correlation measures, wherein each correlation measure is determined for a respective one of a plurality of time shift values and is indicative of a correlation between:
a first set of measurement values derived from the first data set; and
a second set of measurement values derived from the second data set, wherein one of the first and second sets of measurement values are derived under application of a time shift corresponding to the respective time shift value;
select one of the time shift values in dependence on the correlation measures;
determine a synchronization offset based on the selected time shift value; and
use the determined synchronization offset to perform at least one of:
correcting time information in measurement data received from the first source and outputting the corrected measurement data; and
transmitting the synchronization offset to the first source to enable local correction of time information at the first source.
